(19) United States
(12) Patent Application Publication
(10) Pub. No.: US 2026/0182440 A1
(43) Pub. Date: Jun. 25, 2026

(54) EMBEDDED SEMICONDUCTOR DEVICE PACKAGES AND METHODS OF MANUFACTURE

(71) Applicant: SEMICONDUCTOR COMPONENTS INDUSTRIES, LLC, Scottsdale, AZ (US)

(72) Inventors: Ankit Bhushan SHARMA, Erding (DE); Olaf ZSCHIESCHANG, Sinsheim (DE)

(73) Assignee: SEMICONDUCTOR COMPONENTS INDUSTRIES, LLC, Scottsdale, AZ (US)

(21) Appl. No.: 18/989,138

(22) Filed: Dec. 20, 2024

(51) Int. Cl. H01L 23/31; H01L 21/56; H01L 23/36

(52) U.S. Cl. CPC H10W 74/121; H10W 40/10; H10W 74/01

(57) ABSTRACT

In a general aspect, a method includes forming a panel including a heat spreader disposed in a non-conductive material. The heat spreader is exposed on opposite sides of the panel. The method further includes coupling a semiconductor die to a surface of the heat spreader with a conductive bonding material, and applying an underfill material to encapsulate the conductive bonding material. The method also includes plating a contact pad of the semiconductor die, embedding the semiconductor die and the underfill material in a lamination material, and disposing a metal layer on the lamination material. The method further includes forming an opening through the metal layer and the lamination material to expose at least a portion of the plating of the contact pad, and forming a conductive via in the opening. The conductive via electrically couples the metal layer with the plating of the contact pad.

### SUMMARY

In a general aspect, a method for producing a semiconductor device package includes forming a panel including a heat spreader that is disposed in a non-conductive material. A first surface of the heat spreader is exposed through a first side of the non-conductive material and a second surface of the heat spreader is exposed through a second side of the non-conductive material opposite the first side. The method further includes coupling a semiconductor die to the first surface of the heat spreader with a conductive bonding material, applying an underfill material to encapsulate the conductive bonding material, and plating a contact pad of the semiconductor die. The method also includes embedding the semiconductor die and the underfill material in a lamination material, and disposing a metal layer on the lamination material. The method further includes forming an opening through the metal layer and the lamination material to expose at least a portion of the plating of the contact pad, and forming a conductive via in the opening. The conductive via electrically couples the metal layer with the plating of the contact pad.

In another general aspect, a semiconductor device package includes a substrate including a non-conductive material, and a heat spreader disposed in the non-conductive material. A first surface of the heat spreader is exposed through a first side of the non-conductive material. A second surface of the heat spreader is exposed through a second side of the non-conductive material opposite the first side. The package further includes a semiconductor die electrically coupled with the substrate with a conductive bonding material, and an underfill material disposed on the first surface of the heat spreader around at least a portion of a perimeter of the semiconductor die. The underfill material encapsulates the conductive bonding material. The package also includes a lamination material encapsulating the semiconductor die and the underfill material, and a patterned metal layer disposed on the lamination material. The patterned metal layer is electrically coupled with at least one of the semiconductor die or the heat spreader.

### BRIEF DESCRIPTION OF THE DRAWINGS

FIG. 1A is a diagram schematically illustrating a cross-sectional view of an example semiconductor device package.

FIG. 1B is a diagram schematically illustrating a top view of the semiconductor package of FIG. 1A.

FIG. 1C is a diagram schematically illustrating a top view of another semiconductor device package.

FIGS. 2A to 2H are diagrams schematically illustrating an example process for producing a semiconductor device package.

FIG. 3 is flowchart illustrating a method that can be used to implement the process of FIGS. 2A to 2H.

Like reference symbols in the various drawings indicate like elements. Reference numbers for some like elements may not be repeated for all such elements. In certain instances, different reference numbers may be used for like, or similar elements. Some reference numbers for certain elements of a given implementation may not be repeated in each drawing corresponding with that implementation. Some reference numbers for certain elements of a given implementation may be repeated in other drawings corresponding with that implementation, but may not be specifically discussed with reference to each corresponding drawing. The drawings are for purposes of illustrating example implementations and may not necessarily be to scale.

### DETAILED DESCRIPTION

This disclosure relates to packaged semiconductor devices, which can be referred to as packages, semiconductor device packages, modules, assemblies, semiconductor device modules, power semiconductor device modules, semiconductor device assemblies, electronic device assemblies, etc. This disclosure further relates to associated methods for producing such semiconductor device packages, e.g., using printed circuit board (PCB) fabrication and/or embedding technologies. The approaches illustrated and described herein can be used to implement semiconductor device packages (assemblies) that include semiconductor die with thick metallization that are embedded in a lamination material.

In previous techniques and approaches for producing semiconductor packages, thick metallization (e.g., approximately 10 micrometer thick copper) is applied as top level metallization for semiconductor die, typically at the wafer level as part of a semiconductor wafer manufacturing process. One technical problem with such prior implementations is warpage (e.g., wafer and/or die warpage) due to the thermomechanical stresses on the wafer exerted by the thick metallization, which can be formed using galvanic copper deposition (plating). Such warpage can result in damage to a wafer, e.g., one or more semiconductor die included in a wafer, or to an individual semiconductor die. Such damage can include film cracking, wafer cracking and/or die cracking. As wafer and/or semiconductor die thickness decreases, risk of warpage and associated wafer and/or semiconductor die fracture increases. Furthermore, increased wafer sizes also have a higher risk of fracture, film cracking and/or die cracking.

One technical solution to the foregoing technical problem is to apply such thick metallization to a semiconductor die after coupling the semiconductor die to a heat spreader that is included a panel. For instance, a heat spreader can be included in (e.g., embedded in) a panel of non-conductive material, such as printed circuit board material. The semiconductor die can then be embedded in lamination material, e.g., using prepreg material and vacuum lamination. A technical benefit of the foregoing technical solution is that warpage of a corresponding semiconductor die can be reduced or prevented, preventing associated damage. Another technical benefit of the foregoing technical solution is that thick back side (bottom side) metallization disposed on the semiconductor die can be omitted, as the heat spreader can facilitate thermal dissipation from the semiconductor die in place of the thick back side metallization.

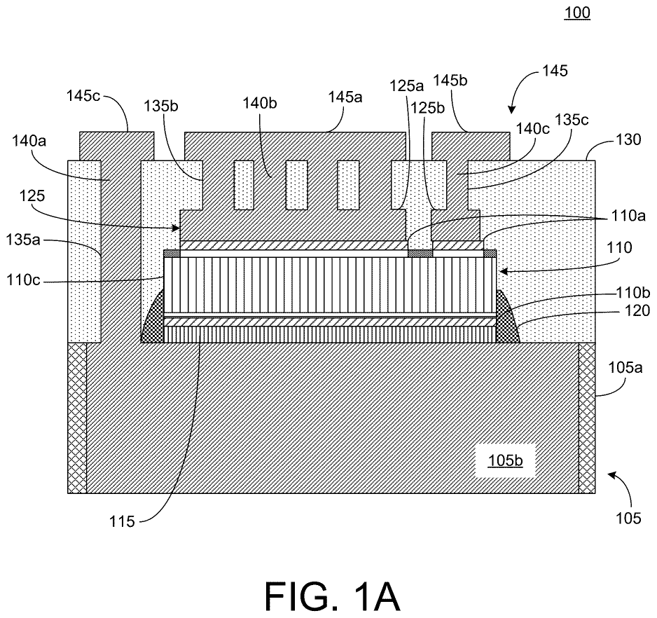

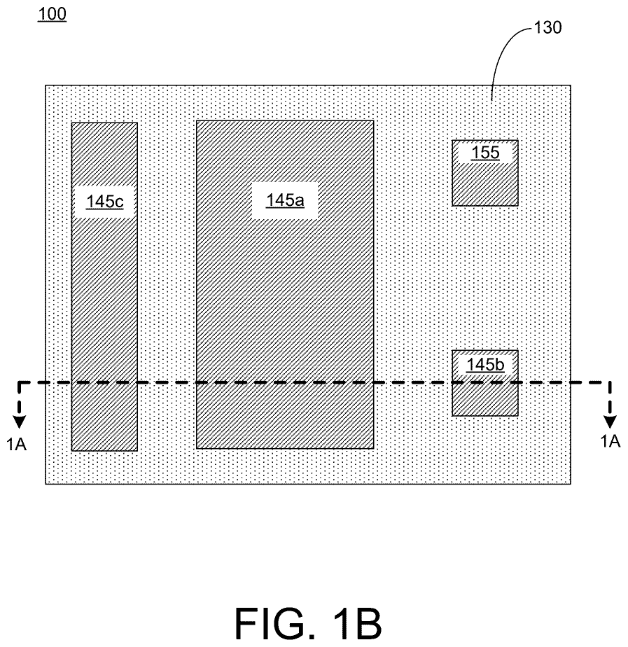

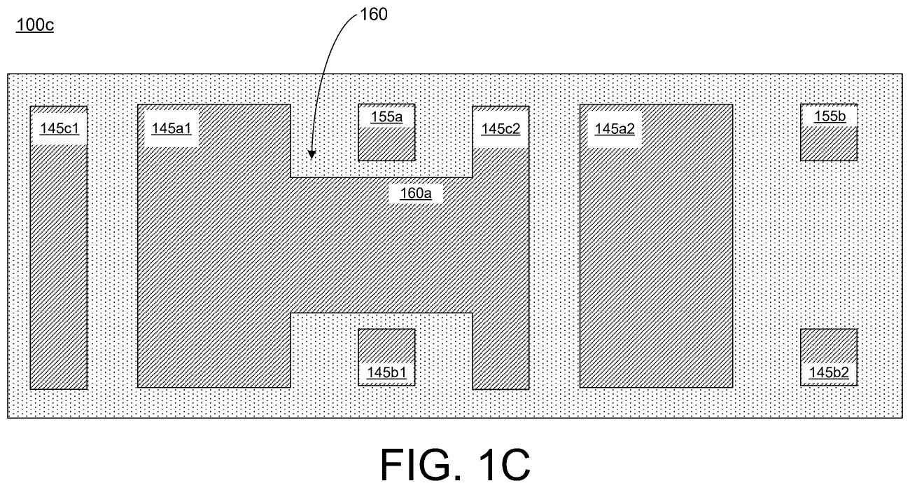

FIG. 1A is a diagram schematically illustrating a cross-sectional view of an example semiconductor device package 100. FIG. 1B is a diagram schematically illustrating a top side view of the semiconductor device package 100. In FIG. 1B, a section line 1A-1A corresponding with the cross-sectional view of FIG. 1A is shown.

As shown in FIG. 1A, the semiconductor device package 100 includes a substrate 105. The substrate 105 can be referred to as a panel, a portion of a panel, etc. In this example, the substrate 105 includes a non-conductive material 105a, which can, e.g., be an elastomeric material, an organic material, a phenolic material, or a PCB/FR-4 material. The substrate 105 further includes a heat spreader 105b. In some implementations, the heat spreader 105b can be a metal plate, a metal coin, a metal slug, which can be formed from a metal with a high thermal conductivity, such as copper. In some implementations, the heat spreader 105b can be a direct-bonded metal substrate, which can include an insulating layer disposed between a first metal layer and a second metal layer. The insulating layer can be, for example, a ceramic layer. In some implementations, the insulating layer can be, or can include, for example, a ceramic material such as alumina (Al₂O₃), aluminum nitride (AlN)), or silicon nitride (Si₃N₄).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process and/or a lamination process.

In some implementations, the first metal layer and/or the second metal layer of a DBM substrate can be, or can function as a heat sink. In some implementations, the first metal layer and/or the second metal layer can be coupled to a heat sink or other heat dissipation component. In some implementations, at least a portion of one or more of the first metal layer or the second metal layer can be exposed through a molding material or non-conductive material, such as the non-conductive material 105a shown in FIG. 1A.

In some implementations, the first metal layer and/or the second metal layer of the DBM substrate can be or can include a patterned metal layer including one or more electrically conductive traces. In some implementations, the first metal layer and/or the second metal layer can be, or can include a patterned layer configured to form one or more electrical circuits, one or more patterned metal layers or metal layer portions, one or more conductive blind and/or through vias, and/or so forth.

In some implementations, a DBM substrate can be, or can include a direct bonded copper (DBC) substrate (e.g., a DBM with copper metal layers). In some implementations, such as in DBC substrate implementations, the first metal layer and/or the second metal layer is a copper layer.

As shown in FIG. 1A, the semiconductor device package 100 includes a semiconductor die 110 that has a top side metallization layer 110a and a bottom side metallization layer 110b (back side metal layer). In this example, the top side metallization layer 110a is a patterned metallization layer, while the bottom side metallization layer 110b is a blanket metal layer (e.g., is not patterned). The semiconductor die 110 is coupled with the semiconductor die 110 via a conductive bonding material 115. In some implementation, the conductive bonding material 115 can include a solder or a sintering material. For instance, in example implementations, the semiconductor die 110 can be coupled with the heat spreader 105b

using a number of different processes, such as soldering processes, sintering processes, or conductive epoxy adhesive processes.

In some implementations, soldering can be, or can include a process of joining two surfaces (e.g., metal surfaces and semiconductor surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal or metal-to-semiconductor type bonding materials.

In some implementations, a coupling of components can be performed using, for example, a solder process, a sintering process (e.g., a silver sintering process, a copper sintering process), and/or other metal-to-metal or metal-to-semiconductor bonding processes.

The semiconductor device package 100 of FIG. 1A also includes an underfill material 120 that is disposed on the heat spreader 105b. The underfill material 120 is also disposed at least a portion of a sidewall 110c, where the sidewall is defined by the semiconductor die 110 (including the bottom side metallization layer 110b) and the conductive bonding material 115. The conductive bonding material 115 can be a non-conductive epoxy material that is disposed around a perimeter of the semiconductor die 110 to encapsulate (seal) the conductive bonding material 115.

In some implementations, the underfill material 120 can be a material having a low viscosity, and that is a different material than the non-conductive material 105a of the substrate 105. The underfill material 120 can prevent contamination of the conductive bonding material 115 and/or prevent outflow of the conductive bonding material 115 during processing operations used to produce the semiconductor device package 100, e.g., processing operations subsequent to formation of the underfill material 120.

The semiconductor device package 100 further includes a metallization layer 125 (e.g., a thick metallization layer) that is disposed on the top side metallization layer 110a. In this example, the metallization layer 125 includes a first portion 125a and a second portion 125b. In some implementations, the metallization layer 125 can be a copper layer that is formed using a plating operation, such as described herein.

In some implementations, the semiconductor die 110 can include a power transistor, such as a power field-effect transistor (FET). In this example, the first portion 125a of the metallization layer 125 can be disposed on a contact pad of the semiconductor die 110 that is electrically coupled with a source terminal and included in the top side metallization layer 110a. Further in this example, the second portion 125b of the metallization layer 125 can be disposed on a contact pad of the semiconductor die 110 that is electrically coupled with a gate terminal of the FET and also included in the top side metallization layer 110a. In this example, a drain terminal of the FET can be coupled with the heat spreader 105b via the conductive bonding material 115 and the bottom side metallization layer 110b.

As shown in FIG. 1A, the semiconductor device package 100 further includes a lamination material 130 that encapsulates the semiconductor die 110, the underfill material 120 and the metallization layer 125. In some implementations, the lamination material 130 can be a prepreg material (e.g., a fiber material that is impregnated with a resin and curing agent). In some implementations, the lamination material 130 can be formed from a plurality of layers, e.g., multiple prepreg material layers. A vacuum lamination process can be performed to facilitate encapsulation of the semiconductor die 110, the underfill material 120 and the metallization layer 125 with the prepreg layers, such as shown in FIG. 1A. In some implementations, the lamination material 130 can have a higher viscosity than the underfill material 120, e.g. to allow for encapsulation without altering the underfill material 120 (e.g., causing a phase change in the underfill material 120). In some implementations, the lamination material 130 can be an epoxy-based material, a polyimide based material, or other material.

The lamination material 130 of the semiconductor device package 100 has a plurality of openings defined therein. For instance, an opening 135a is defined in the lamination material 130 and, as shown in FIG. 1A, the opening 135a extends from an upper surface of the lamination material 130 to a surface of the heat spreader 105b. Openings 135b are also defined in the lamination material 130, and respectively extend from the upper surface of the lamination material 130 to a surface of the first portion 125a of the metallization layer 125. Similarly, an opening 135c is defined in the lamination material 130, and extends from the upper surface of the lamination material 130 to a surface of the second portion 125b of the metallization layer 125. The openings 135a, 135b and 135c are shown by way of example. In some implementations additional or fewer openings can be defined in the lamination material 130. For instance, a plurality of openings 135a can be defined in the lamination material 130, e.g., a row of openings that are disposed in a line with the opening 135a shown in FIG. 1A, e.g., into the page. In some implementations, the semiconductor device package 100 can include fewer or more of the openings 135b. For instance, an array of the openings 135b can be defined in the lamination material 130. In some implementations, the semiconductor device package 100 could also include additional openings 135c in the lamination material 130, e.g., a row of openings that are disposed in line with the opening 135c shown in FIG. 1A, e.g., into the page.

As shown in FIG. 1A, respective conductive vias are disposed in the openings 135a, 135b and 135c. For instance, a conductive via 140a is disposed in the opening 135a, conductive vias 140b are disposed in the openings 135b, and a conductive via 140c is disposed in the opening 135c. In some implementations, additional conductive vias (or fewer conductive vias) can be included, e.g., one in each of the openings 135a, 135b and 135c that are defined in the lamination material 130.

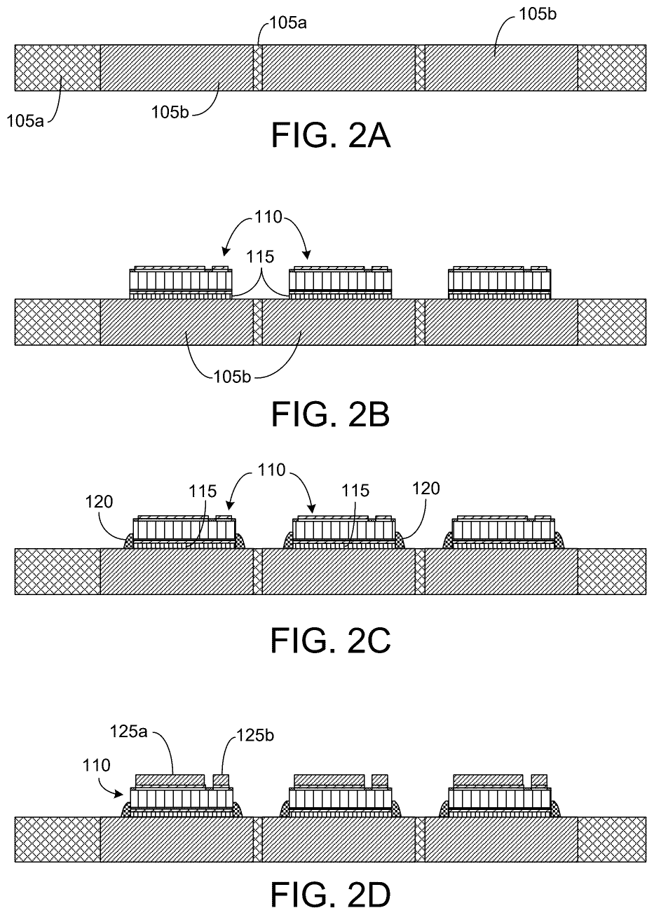

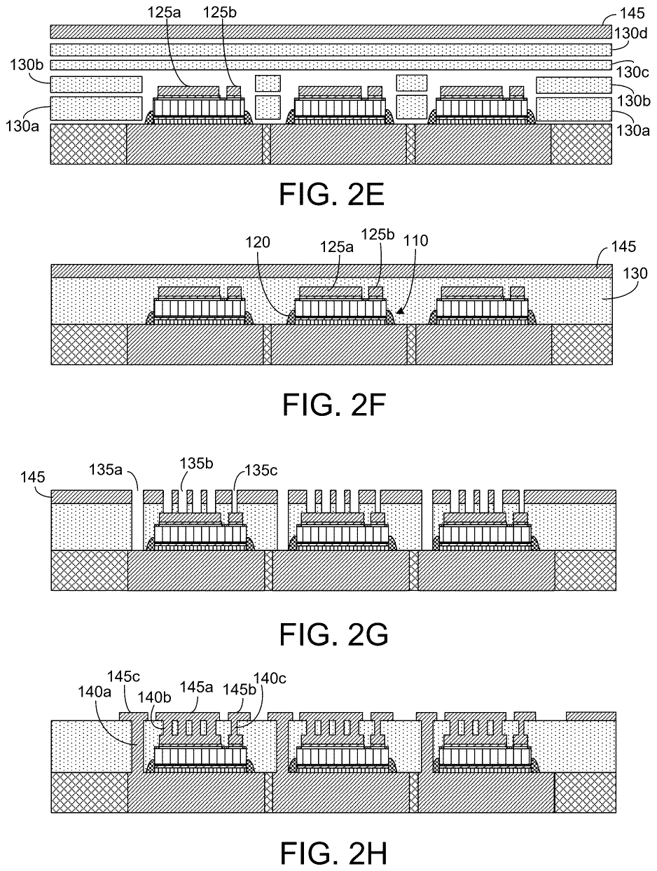

As further shown in FIG. 1A, the semiconductor device package 100 can include a metal layer 145 that is patterned to define a first portion 145a, a second portion 145b and a third portion 145c. The metal layer 145 can be formed using one or more processes, such as those illustrated and described below with respect to, at least, FIGS. 2E to 2H. In the semiconductor device package 100, the first portion 145a of the metal layer 145 is electrically coupled with the first portion 125a of the metallization layer 125 by the conductive vias 140b. The second portion 145b of the metal layer 145 is electrically coupled with the second portion 125b of the metallization layer 125 by the conductive via 140c. The third portion 145c of the metal layer 145 is electrically coupled with the heat spreader 105b by the conductive via 140a.

The semiconductor die 110 of the semiconductor device package 100 can be referred to as being an embedded semiconductor die, that is, the semiconductor die 110 is embedded in the lamination material 130, e.g., by disposing a plurality of lamination material layers on the substrate 105 and performing a lamination process (e.g., vacuum lamination process) to embed (e.g., encapsulate) the semiconductor die 110 in the lamination material 130, e.g., as shown FIG. 1A.

As shown in FIG. 1B, the first portion 145a, the second portion 145b, and the third portion 145c of the metal layer 145 can be disposed on the lamination material 130 of the semiconductor device package 100, and be formed as contiguous metallization with the conductive vias 140b, 140c and 140a to provide electrical connections as described with respect to FIG. 1A. As noted above, the semiconductor device package 100 can include additional conductive vias than those shown in FIG. 1A. For instance, a plurality of conductive via 140a could be included in a line beneath the third portion 145c of the metal layer 145 and/or an array of conductive vias 140b could be included beneath the first portion 145a of the metal layer 145.

As shown in FIG. 1B, the semiconductor device package 100 also includes metallization 155,which can be a fourth portion of the metal layer 145, or could be formed separately from the metal layer 145. In this example, the semiconductor device package 100 can include a semiconductor die including a power transistor, such as a FET transistor, and the metallization 155 can provide an electrical connection (using respective conductive vias) to a thermal sense device, such as a positive-temperature-coefficient (PTC) device, or can provide an electrical connection for source voltage/current sensing for the FET transistor. In some implementations, additional metallization can also be included to facilitate other electrical connections for the semiconductor device package 100.

FIG. 1C, is a diagram schematically illustrating another example semiconductor device package 100c that can be produced using the approaches described herein. In this example, the semiconductor device package 100c can implement a half-bridge circuit, e.g. can include a first semiconductor die including a high-side power FET and a second semiconductor die including a low-side power FET. In this example, each of the semiconductor die of the semiconductor device package 100c can be respectively embedded in the lamination material 130, and the semiconductor device package 100c can be produced using the approaches described herein. For instance, the semiconductor device package 100c can be produced as part of a panel in which a plurality of embedded semiconductor die are included. The semiconductor device package 100c, as well as other semiconductor device packages, can then be singulated (cut, separated, etc.) from the corresponding panel. In some implementations, semiconductor device packages produced in such a panel can implement circuits of a same configuration, or can implement circuits of different configurations. Accordingly, the half-bridge circuit of FIG. 1C is given by way of example and for purposes of illustration.

In the half-bridge circuit example of FIG. 1C, a metal layer portion 145c1 can be electrically coupled with a drain terminal of the high-side power FET of the half-bridge circuit. That is, the metal layer portion 145c1 can implement a power supply (DC+) terminal of the half-bridge circuit. Further in this example, a metal layer portion 145a1 can be electrically coupled with a source terminal of the high-side power FET, a metal layer portion 145c2 can be electrically coupled with a drain terminal of the low-side power FET of the half-bridge circuit, and a metal layer portion 160a can electrically couple the metal layer portion 145a1 with the metal layer portion 145c2 to define metallization 160. That is, the metallization 160 can implement an output (AC) terminal of the half-bridge circuit. Also in the example of FIG. 1C, a metal layer portion 145a2 can be electrically coupled with a source terminal of the low-side power FET. That is, the metal layer portion 145a2 can implement a ground (DC−) terminal of the half-bridge circuit.

Still further in the example of FIG. 1C, a metal layer portion 145b1 can be electrically coupled with a gate terminal of the high-side power FET, a metal layer portion 145b2 can be electrically coupled with a gate terminal of the low-side power FET, a metal layer portion 155a can be coupled to a thermal sensing device of the high-side power FET, and a metal layer portion 155b can be electrically coupled with a thermal sensing device of the low-side power FET. In some implementations, the semiconductor device package 100c can implement a different circuit, and the metal layer portions and metallization of the semiconductor device package 100c can implement respective terminals of that circuit.

FIGS. 2A to 2H are diagrams schematically illustrating a manufacturing process for producing a semiconductor device package, such as the semiconductor device package 100 of FIGS. 1A and 1B. For purposes of illustration, FIGS. 2A to 2H are cross-sectional views corresponding with the section line 1A-1A in FIG. 1B. Accordingly, by way of example and for purposes of illustration, the process of FIGS. 2A to 2H is described with further reference to FIGS. 1A and 1B, using like 100-series reference numbers. For purposes of clarity, some structure is not shown in FIGS. 2A to 2H, such as structure that is behind structure disposed along the section line 1A-1A in FIG. 1B, where that structure, if illustrated, would obscure the illustrated views. For instance, portions of the lamination material layers in FIG. 2E are not shown, and structure behind the openings in FIG. 2G is not shown.

As shown in FIG. 2A, a panel is produced, where the panel includes a plurality of heat spreaders 105b that are included in non-conductive material 105a. The heat spreaders 105b can be referred to as being embedded in (surrounded by, set in, etc.) the non-conductive material 105a. As discussed with respect to FIG. 1A, the non-conductive material 105a can, as some examples, be an elastomeric material, an organic material, a phenolic material, or a PCB/FR-4 material. While three heat spreaders 105b (and their corresponding structures) are shown in FIGS. 2A to 2H, in some implementation, a panel can include additional heat spreaders 105b, that can be used for producing corresponding semiconductor device packages.

As shown in FIG. 2B, semiconductor die 110 can be respectively coupled with the heat spreaders 105b using conductive bonding material 115, e.g., solder, sinter material, or other conductive bonding material. In some implementations, each of the semiconductor die 110 can implement a same device, e.g., FETs or other devices. In some implementations, the semiconductor die 110 can implement different devices, e.g., FETs and fast-recovery diodes (FRDs), or other combinations. In some implementations, a semiconductor device package can include two or more heat spreaders 105b, along with corresponding non-conductive material 105a, semiconductor die 110, associated lamination material (e.g., lamination material 130) and electrical interconnections, such as conductive vias and metallization layers.

For instance, in some implementations, one or more semiconductor die (e.g., one or more semiconductor components) of a semiconductor device package can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRD), a diode, and/or so forth. In some implementations, one or more semiconductor die can be (e.g., can be a portion of), or can include a component for an electrical vehicle (EV).

In some implementations, different semiconductor die of a semiconductor device package (when more than one semiconductor die is included) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT or MOSFET can be fabricated using a SiC substrate, while a controller can be fabricated using a silicon substrate.

In example implementations, a first semiconductor die can be connected to a second semiconductor die, for example, by an electrical connection (e.g., a wire bond, an electrical clip, metal traces, etc.) extending from the first die to the second die, such as portions of the metal layer 145 extending between conductive vias that are respectively electrically coupled with the first semiconductor die and the second semiconductor die.

As shown in FIG. 2C, the underfill material 120 can be formed on the heat spreader 105b around respective perimeters of the semiconductor die 110, where the underfill material 120 respectively encapsulates the conductive bonding material 115 of each semiconductor die 110, e.g., is also disposed on the underfill material 120 and at least a portion of respective side walls of the semiconductor die 110. In some implementations, the underfill material 120 can at least partially surround the respective perimeters of the semiconductor die 110, or can completely surround their perimeters. In some implementations, forming the underfill material 120 can include depositing a low-viscosity epoxy material followed by a cure operation, such as a bake operation.

FIG. 2D illustrates formation of the portions 125a and 125b of the metallization layer 125. In some implementations, the portions 125a and 125b of the metallization layer 125 can be formed using a plating operation, e.g., an electroless copper plating operation. In some implementations, the metallization layer 125 can have a thickness of 10 micrometers (μm) or greater. For instance, in some implementations, the metallization layer 125 can have a thickness of 25 μm, 50 μm, 100 μm, etc.

FIG. 2E illustrates layering of lamination material layers for embedding the semiconductor die 110. As shown in FIG. 2E, a lamination material layer 130a and a lamination material layer 130b can be disposed on the panel, where the lamination material layer 130a and the lamination material layer 130b include openings that respectively surround the semiconductor die 110 and their corresponding underfill material 120. As also shown in FIG. 2E, a lamination material layer 130c is disposed on the lamination material layer 130b, and a lamination material layer 130d is disposed on the lamination material layer 130c, where the lamination material layer 130c covers the openings defined by the lamination material layer 130a and the lamination material layer 130b. A metal layer 145, e.g., a copper metal layer, is disposed on the lamination material layer 130d, where the metal layer 145 can define, at least in part, the metal layer portions 145a, 145b and 145c of the semiconductor device package 100 in FIGS. 1A and 1B.

In this example, the openings of the lamination material layers 130a and 130b are larger than the perimeters of the semiconductor die 110 and the underfill material 120. That is, sidewalls of the openings are respectively spaced from the semiconductor die 110 and their corresponding underfill material 120. Also in this example, a combined thickness of the lamination material layer 130a and the lamination material layer 130b (measured from the respective exposed surfaces of the heat spreaders 105b) can be greater than respective thicknesses of the semiconductor die 110 and the conductive bonding material 115, such that the lamination material layer 130c is spaced from the metallization layer 125 (e.g., is spaced from upper surfaces of the first portion 125a and the second portion 125b). These spacings allow for the lamination material, during a lamination operation, to flow around the semiconductor die 110 and the underfill material 120 to embed (encapsulate) them in the lamination material.

As shown in FIG. 2F, a lamination process (e.g., a vacuum lamination process) is performed to produce the lamination material 130 from the lamination material layers 130a to 130d (e.g., prepreg material layers). For instance, with the structure shown in FIG. 2E being disposed in a vacuum chamber, mechanical pressure can be applied to the metal layer 145 and, as a result, the lamination material layers 130a to 130d. Heat can then be applied to cause material of the lamination material layers 130a to 130b to flow and embed the semiconductor die 110 and the underfill material 120 in the lamination material 130.

FIG. 2G illustrates formation of the openings 135a, 135b and 135c in the lamination material 130 (and the metal layer 145 in this example). In some implementations, the openings 135a to 135c can be formed using laser ablation, mechanical milling, etching, etc. In some implementations, the openings 135a to 135c can be micro-via openings, e.g., openings with dimensions of micrometer scale.

After forming the openings 135a to 135c, as shown in FIG. 2H, a plating operation (e.g., a galvanic copper plating operation) can be performed to form the conductive vias 140a, 140b and 140c, as well as form additional metallization on the upper surface of the lamination material 130. Photolithography and etch operations can then be performed to define the metal layer portions 145a, 145b and 145c (and/or other metal layer portions as appropriate for a particular implementation).

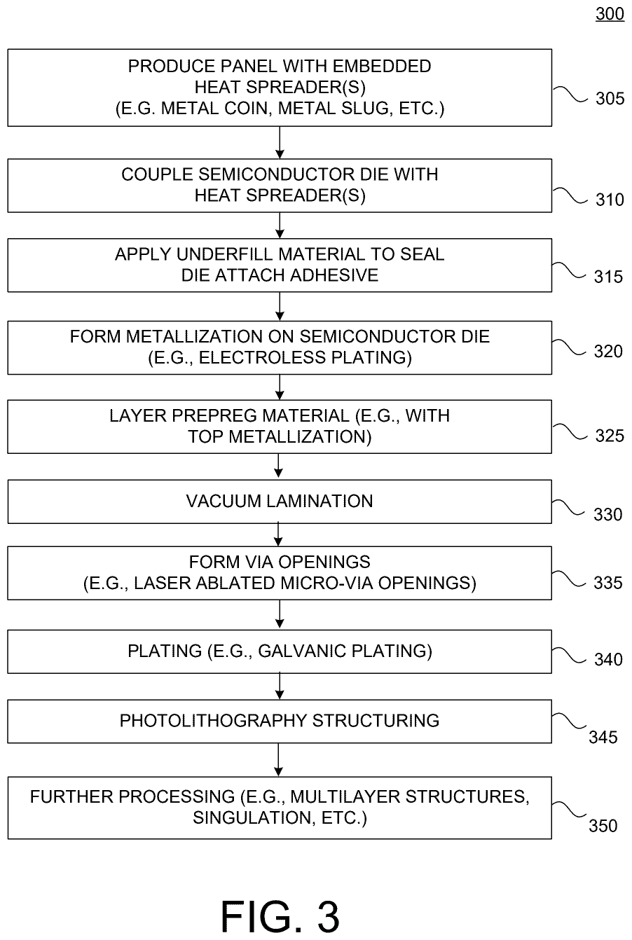

FIG. 3 is a flowchart illustrating a method 300 for producing a semiconductor device assembly. In some implementations, the method 300 can be implemented using the process of FIGS. 2A to 2H to produce the semiconductor device package 100 of FIGS. 1A and 1B. Accordingly, for purpose of illustration, the method 300 is described with further reference to FIGS. 1A, 1B and 2A to 2H.

At operation 305, the method 300 includes producing a panel with embedded heat spreaders, such as the panel of FIG. 2A. In some implementations, the heat spreaders can be metal plates, metal coins, metal slugs or DBM substrates that are embedded in a non-conductive material, such as a PCB material. At operation 310, the method 300 includes coupling respective semiconductor die with the heat spreaders using a conductive bonding material (conductive bonding material 115). The operation 310 can include coupling the semiconductor die with the heat spreaders using soldering, sintering, or other attachment process. At operation 315, an underfill material, such as the underfill material 120, can be applied to seal the conductive bonding material 115 of the respective semiconductor die.

At operation 320, a plating operation can be performed to form metallization (e.g., portions 125a and 125b of the metallization layer 125) on contact pads of the semiconductor die. The plating operation at operation 320 can be an electroless copper plating operation. At operation 325, lamination material layers (and a metal layer) can be disposed on the panel, such as the arrangement of the lamination material layers 130a to 130d and the metal layer 145 in FIG. 2E. At operation 330, a vacuum lamination operation can be performed to embed the semiconductor die in a lamination material, such as in the lamination material 130 illustrated in FIG. 2F. At operation 335, openings (via openings) are formed, such as the openings 135a, 135b and 135c of the semiconductor device package 100 (e.g., as shown FIG. 2G). At operation 340, a plating operation can be performed (e.g., a galvanic copper plating operation) to form conductive vias, such as the conductive vias 140a to 140c, as well as to form metallization (e.g., additional metallization) on an upper surface of the lamination material of operation 330. At operation 345, photolithography structuring of the metallization on the surface of the lamination material can be performed, e.g., to define the metal layer portions 145a to 145c of the semiconductor device package 100. At operation 350, additional processing can be performed. Such additional processing can include separating the panel into individual semiconductor device packages including one or more semiconductor die (along with corresponding heat spreaders and other structure formed by the operations 305-345).

In some implementations, such further processing can include forming additional structures, which can include other semiconductor die. Such additional structures can, e.g., be formed on top of the structures formed by the operations 305 to 345. That is, semiconductor device packages (or modules) formed using the method 300 (and/or the process of FIGS. 2A to 2H) can be included in another package or module. For example, one or more modules or packages can be one or more sub modules or packages included within another module or package. In other words, a first module or package can be included as a sub module or package within a second module or package.

In a general aspect, a method for producing a semiconductor device package includes forming a panel including a heat spreader that is disposed in a non-conductive material. A first surface of the heat spreader is exposed through a first side of the non-conductive material and a second surface of the heat spreader is exposed through a second side of the non-conductive material opposite the first side. The method further includes coupling a semiconductor die to the first surface of the heat spreader with a conductive bonding material, applying an underfill material to encapsulate the conductive bonding material, and plating a contact pad of the semiconductor die. The method also includes embedding the semiconductor die and the underfill material in a lamination material, and disposing a metal layer on the lamination material. The method further includes forming an opening through the metal layer and the lamination material to expose at least a portion of the plating of the contact pad, and forming a conductive via in the opening. The conductive via electrically couples the metal layer with the plating of the contact pad.

Implementations can include one or more of the following features or aspects, alone or in combination. For example, embedding the semiconductor die and the underfill material in the lamination material can include disposing first lamination material on the panel, where the first lamination material can have an opening surrounding and spaced from the semiconductor die and underfill material. A thickness of the first lamination material from the first side of the panel can be greater than a thickness of the semiconductor die and the plating of the contact pad from the first side of the panel. The method can include disposing a second lamination material on the first lamination material. The second lamination material can cover the opening of the first lamination material and be spaced from the semiconductor die and the plating of the contact pad. The method can include performing a vacuum lamination operation to embed the semiconductor die, the plating of the contact pad and the underfill material in the first lamination material and the second lamination material.

The first lamination material can include at least a first layer of prepreg material. The second lamination material can include at least a second layer of prepreg material.

Forming the opening through the metal layer and the lamination material can include forming the opening using laser ablation.

The method can include patterning the metal layer.

Plating the contact pad of the semiconductor die can include plating a plurality of contact pads of the semiconductor die. Forming the opening through the metal layer and the lamination material to expose the plating of the contact pad can include forming respective openings through the metal layer and the lamination material to expose respective plating of the plurality of contact pads. Forming the conductive via in the opening can include forming respective conductive vias in the respective openings.

Forming the respective openings through the metal layer and the lamination material can include forming the respective openings using laser ablation.

Plating the contact pad can include plating the contact pad using one of electroless copper plating or galvanic copper plating.

Forming the conductive via can include forming the conductive via using galvanic copper plating.

The opening through the metal layer and lamination material can be a first opening and the conductive via can be a first conductive via. The method can include forming a second opening through the metal layer and the lamination material to expose a portion of the heat spreader. The method can include forming a second conductive via in the second opening. The second conductive via can electrically couple the metal layer with the heat spreader.

The non-conductive material of the panel can include a printed circuit board material. The underfill material can include a non-conductive epoxy material. The lamination material can include a prepreg material.

In another general aspect, a semiconductor device package includes a substrate including a non-conductive material, and a heat spreader disposed in the non-conductive material. A first surface of the heat spreader is exposed through a first side of the non-conductive material. A second surface of the heat spreader is exposed through a second side of the non-conductive material opposite the first side. The package further includes a semiconductor die electrically coupled with the substrate with a conductive bonding material, and an underfill material disposed on the first surface of the heat spreader around at least a portion of a perimeter of the semiconductor die. The underfill material encapsulates the conductive bonding material. The package also includes a lamination material encapsulating the semiconductor die and the underfill material, and a patterned metal layer disposed on the lamination material. The patterned metal layer is electrically coupled with at least one of the semiconductor die or the heat spreader.

Implementations can include one or more of the following features or aspects, alone or in combination. For example, the non-conductive material, the underfill material and the lamination material can be different materials.

The non-conductive material can be a printed circuit board material. The underfill material can be a non-conductive epoxy material. The lamination material can be a prepreg material.

The package can include copper plating disposed on a contact pad of the semiconductor die. The patterned metal layer can be electrically coupled to the copper plating with a conductive via defined in the lamination material.

A first portion of the patterned metal layer can be electrically coupled to the heat spreader with a first conductive via defined in the lamination material. A second portion of the patterned metal layer can be electrically coupled to the semiconductor die with a second conductive via defined in the lamination material.

A third portion of the patterned metal layer can be electrically coupled with the semiconductor die with a third conductive via defined in the lamination material.

The conductive bonding material can be one of a solder material, a sintering material, or an electrically conductive epoxy.

The underfill material can be disposed around an entire perimeter of the semiconductor die; and disposed on at least a portion of a sidewall of the semiconductor die.

The heat spreader can include a metal plate.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A method for producing a semiconductor device package, the method including:
forming a panel including a heat spreader that is disposed in a non-conductive material, a first surface of the heat spreader being exposed through a first side of the non-conductive material and a second surface of the heat spreader being exposed through a second side of the non-conductive material opposite the first side;
coupling a semiconductor die to the first surface of the heat spreader with a conductive bonding material;
applying an underfill material to encapsulate the conductive bonding material;
plating a contact pad of the semiconductor die;
embedding the semiconductor die and the underfill material in a lamination material;
disposing a metal layer on the lamination material;
forming an opening through the metal layer and the lamination material to expose at least a portion of the plating of the contact pad; and
forming a conductive via in the opening, the conductive via electrically coupling the metal layer with the plating of the contact pad.

2. The method of claim 1, wherein embedding the semiconductor die and the underfill material in the lamination material includes:
disposing first lamination material on the panel, the first lamination material having an opening surrounding and being spaced from the semiconductor die and underfill material, a thickness of the first lamination material from the panel being greater than a thickness of the semiconductor die and the plating of the contact pad from the panel;
disposing a second lamination material on the first lamination material, the second lamination material covering the opening of the first lamination material and being spaced from the semiconductor die and the plating of the contact pad; and
performing a vacuum lamination operation to embed the semiconductor die, the plating of the contact pad and the underfill material in the first lamination material and the second lamination material.

3. The method of claim 2, wherein:
the first lamination material includes at least a first layer of prepreg material; and
the second lamination material includes at least a second layer of prepreg material.

4. The method of claim 1, wherein forming the opening through the metal layer and the lamination material includes forming the opening using laser ablation.

5. The method of claim 1, further comprising patterning the metal layer.

6. The method of claim 1, wherein:
plating the contact pad of the semiconductor die includes plating a plurality of contact pads of the semiconductor die;
forming the opening through the metal layer and the lamination material to expose the plating of the contact pad includes forming respective openings through the metal layer and the lamination material to expose respective plating of the plurality of contact pads; and
forming the conductive via in the opening includes forming respective conductive vias in the respective openings.

7. The method of claim 6, wherein forming the respective openings through the metal layer and the lamination material includes forming the respective openings using laser ablation.

8. The method of claim 1, wherein plating the contact pad includes plating the contact pad using one of:
electroless copper plating; or
galvanic copper plating.

9. The method of claim 1, wherein forming the conductive via includes forming the conductive via using galvanic copper plating.

10. The method of claim 1, wherein the opening is a first opening and the conductive via is a first conductive via, the method further comprising:
forming a second opening through the metal layer and the lamination material to expose a portion of the heat spreader; and
forming a second conductive via in the second opening, the second conductive via electrically coupling the metal layer with the heat spreader.

11. The method of claim 1, wherein:
the non-conductive material of the panel includes a printed circuit board material;
the underfill material includes a non-conductive epoxy material; and
the lamination material includes a prepreg material.

12. A semiconductor device package comprising:
a substrate including:
a non-conductive material; and
a heat spreader disposed in the non-conductive material, a first surface of the heat spreader being exposed through a first side of the non-conductive material, and a second surface of the heat spreader being exposed through a second side of the non-conductive material opposite the first side;
a semiconductor die electrically coupled with the substrate with a conductive bonding material;
an underfill material disposed on the first surface of the heat spreader around at least a portion of a perimeter of the semiconductor die, the underfill material encapsulating the conductive bonding material;
a lamination material encapsulating the semiconductor die and the underfill material; and
a patterned metal layer disposed on the lamination material, the patterned metal layer being electrically coupled with at least one of the semiconductor die or the heat spreader.

13. The semiconductor device package of claim 12, wherein the non-conductive material, the underfill material and the lamination material are different materials.

14. The semiconductor device package of claim 12, wherein:
the non-conductive material is a printed circuit board material;
the underfill material is a non-conductive epoxy material; and
the lamination material is a prepreg material.

15. The semiconductor device package of claim 12, further comprising copper plating disposed on a contact pad of the semiconductor die, the patterned metal layer being electrically coupled to the copper plating with a conductive via defined in the lamination material.

16. The semiconductor device package of claim 12, wherein:
a first portion of the patterned metal layer is electrically coupled with the heat spreader with a first conductive via defined in the lamination material; and
a second portion of the patterned metal layer is electrically coupled with the semiconductor die with a second conductive via defined in the lamination material.

17. The semiconductor device package of claim 16, wherein a third portion of the patterned metal layer is electrically coupled with the semiconductor die with a third conductive via defined in the lamination material.

18. The semiconductor device package of claim 12, wherein the conductive bonding material is one of:
a solder material;
a sinter material; or
an electrically conductive epoxy.

19. The semiconductor device package of claim 12, wherein the underfill material is:
disposed around an entire perimeter of the semiconductor die; and
disposed on at least a portion of a sidewall of the semiconductor die.

20. The semiconductor device package of claim 12, wherein the heat spreader includes one of:
a metal plate; or
a direct-bonded metal substrate.
